(19) United States
(12) Patent Application Publication
(10) Pub. No.: US 2002/0025671 A1
(43) Pub. Date: Feb. 28, 2002

(54) Method of manufacturing a metal line in a semiconductor device

(76) Inventor: Sung Gyu Pyo, Kyungki-do (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/879,324

(22) Filed: Jun. 12, 2001

(30) Foreign Application Priority Data
Jun. 26, 2000 (KR) 2000-35350

(51) Int. Cl. H01L 21/4763; H01L 21/44

(52) U.S. Cl. 438/638; 438/678; 438/687

(57) ABSTRACT

A method of manufacturing a metal line in a semiconductor device. The method includes forming a diffusion barrier layer on the entire structure in which a damascene pattern is formed, depositing a copper precursor by means of spin-on process, forming a porous copper layer by baking process, performing a hydrogen annealing process and a force filling process to form a copper seed layer at the bottom of the damascene pattern, depositing copper by an electroless-plating method so that the damascene pattern can be sufficiently filled, and forming a copper line by means of a chemical mechanical polishing process. Therefore, the disclosed method allows a selective copper deposition process by electroless-plating method since it can uniformly form a copper seed layer of a good quality at the bottom of the damascene pattern.

### BACKGROUND OF THE INVENTION

1. Field of the Invention

The invention relates generally to a method of manufacturing a metal line in a semiconductor device. More particularly, the present invention relates to a method of manufacturing a metal line in a semiconductor device wherein a copper seed layer of a high quality is uniformly formed at a bottom portion of a damascene pattern to form a selective copper line.

2. Description of the Prior Art

In forming a metal line in a semiconductor device, a copper thin film has a high melting point compared to aluminum and thus has a high resistance against the electro-migration. Thus, the use of copper can improve reliability of a semiconductor device. Also, the copper thin film has a low resistivity (1.7 μΩcm), it can increase the signal transfer speed. Therefore, a method of manufacturing a copper thin film is a technology necessary in a high-speed device and a high-integration device.

Current copper thin films are formed by use of electro-planting method. The electroplating method, however, is problematic due to its high cost and because of its complicated chemical property, the electroplanting method is also sensitive to a process of depositing a seed layer. In other words, in the electroplating method, copper ions that are moved by electromagnetic field that flows along the seed layer are deposited. If the seed layer is not uniformly deposited, however, a potential drop is generated which results in an irregular electroplating deposition. Due to this, voids are generated in the via and trench structure, thereby degrading the property of the copper line.

### SUMMARY OF THE DISCLOSURE

A method of manufacturing a metal line in a semiconductor device is disclosed, by which after a copper precursor is deposited by spin-on process, a uniform and good copper seed layer is formed by simultaneously performing a hydrogen reduction annealing process and a force filling process and copper is then deposited by electroless-plating method to form a selective copper line.

One disclosed method of manufacturing a metal line in a semiconductor device comprises the steps of providing a substrate in which a damascene pattern is formed in an interlayer insulating film, forming a diffusion barrier layer on the entire structure in which the damascene pattern is formed, depositing a copper precursor on the diffusion barrier layer by means of spin-on process, changing the copper precursor into a porous copper layer by baking process, performing hydrogen annealing process and force filling process for the porous copper layer to form a copper seed layer at the bottom of the damascene pattern, depositing copper by electroless-plating method so that the damascene pattern can be sufficiently filled, and forming a copper line by means of chemical mechanical polishing method.

### BRIEF DESCRIPTION OF THE DRAWINGS

The aforementioned aspects and other features of the disclosed method will be explained in the following description, taken in conjunction with the accompanying drawing, wherein:

FIGS. 1A to 1G are cross-sectional views for explaining a method of manufacturing a metal line in a semiconductor device.

### DETAILED DESCRIPTION OF THE PRESENTLY PREFERRED EMBODIMENTS

The present invention will be described in detail by way of a preferred embodiment with reference to an accompanying drawing.

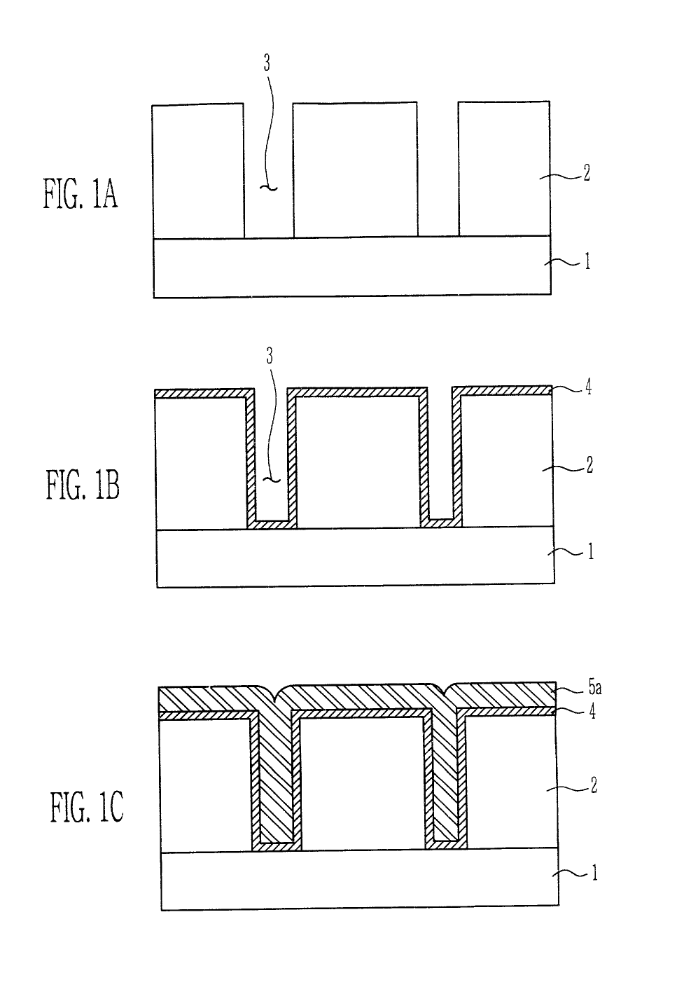

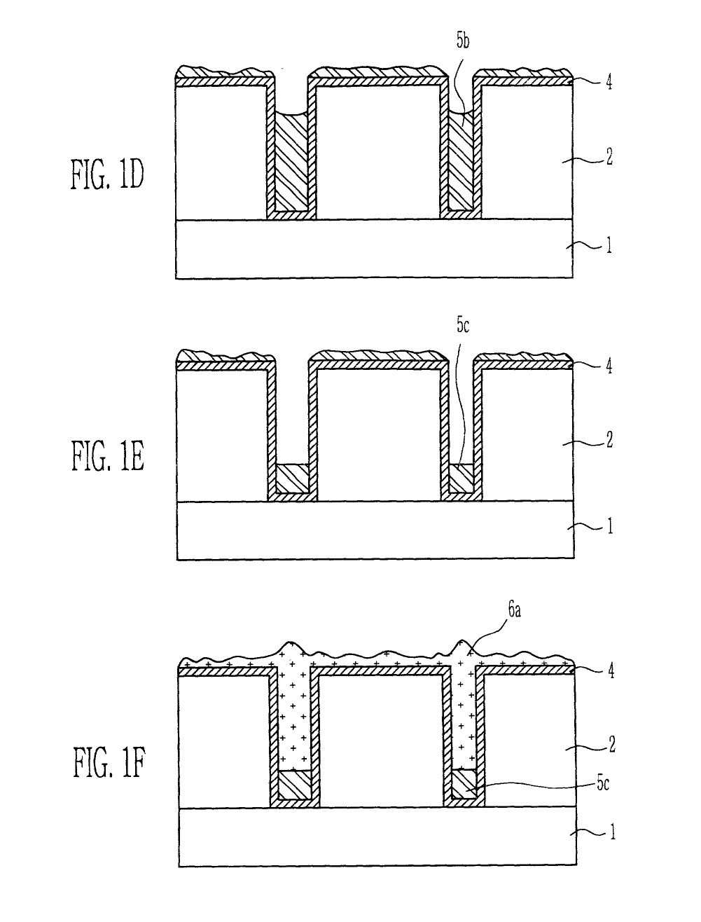

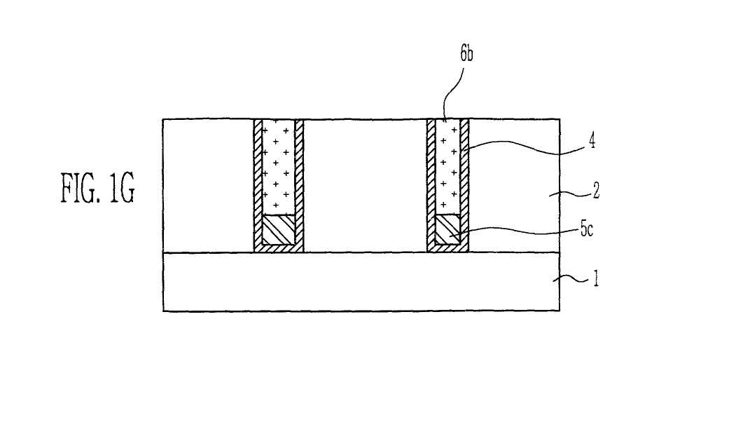

FIGS. 1A through 1G are cross-sectional views for explaining a method of manufacturing a metal line in a semiconductor device. Referring now to FIG. 1A, an interlayer insulating film 2 is formed on a substrate 1 in which various components for forming a semiconductor device are formed. Then, a damascene pattern 3 consisted of a via and/or a trench is formed by single damascene or dual damascene method. Next, in order to remove the by-products generated when the damascene pattern 3 is formed, cleaning process is performed.

In the above process, the interlayer insulating film 2 is formed of an insulating material having a low dielectric constant (k) by means of spin-on or chemical vapor deposition (CVD) method. The cleaning process may employ RF plasma in case a base layer constituting the bottom of the damascene pattern 3 is made of tungsten (Ti), aluminum (Al), etc. and may employ a reactive cleaning process in case that the base layer is made of copper (Cu).

Referring now to FIG. 1B, a diffusion barrier layer 4 is formed on the interlayer insulating film 2 including the damascene pattern 3. At this time, the barrier layer 4 may be formed of ionized PVD TiN, CVD TiN and MOCVD TiN thin films, or ionized PVD Ta, ionized PVD TaN, CVD Ta, CVD TaN, CVD WN, PVD TiAlN, PVD TiSiN, PVD TaSiN, CVD TiAlN, CVD TiSiN, CVD TaSiN thin films.

Referring now to FIG. 1C, a Cu precursor is spin-on deposited at the temperature from about 10° C. to about 100° C. at the rate from about 100 rpm about 8000 rpm to form a spin-on copper layer 5a. When the spin-on copper layer 5a is formed, the number of rotation is controlled so that the thickness of the spin-on copper layer 5a is less 2000 Å, so that the thickness of the seed layer can be from about 100 Å to about 500 Å after subsequent processes such as baking, hydrogen reduction annealing and force filling process will have been performed.

Referring now FIG. 1D, in order to remove polymer components existing in the spin-on copper layer 5a, baking process is performed. Because polymer components existing in the spin-on copper layer Sa are removed by the baking process, the spin-on copper layer 5a becomes a film of porous quality and during the baking process and some of the spin-on copper layer 5a is changed into a porous copper layer 5a existing in the shape of a copper oxide film.

In the above process, the baking process is performed in a single step or a multi-step under a hydrogen atmosphere at the temperature ranges from about 200° to about 500° C. for a time period ranging from about 1 second to about 10 minutes, using only H₂ or a hydrogen mixture gas such as H₂+Ar(1˜95%) or H₂ +N₂(1˜95%), etc.

In case of single step, the baking is performed at a single temperature of a temperature ranging from about 200° C. to about 500° C. for a time period ranging from about 1 second to about 10 minutes. In case of multi-step, the baking is performed at various temperatures ranging from about 200° C. to about 500° C. for a time period ranging from about 1 second to about 10 minutes.

Referring now to FIG. 1E, the hydrogen reduction annealing process and the force filling process are simultaneously performed to increase the density of the porous copper layer Sb and to remove the copper oxide film, thus forming a copper seed layer 5c, which are uniform and good, at the bottom of the damascene pattern 3.

In the above process, the hydrogen reduction annealing process and the force filling process are sequentially performed after the baking process, and are performed under a hydrogen atmosphere at a pressure ranging from about 0.1 MPa to about 100 MPa at the temperature ranging from about 200° C. to about 500° C. for a time period ranging from about 1 to about 10 minutes using only H₂ or a hydrogen mixture gas such as H₂+Ar (1˜95%), H₂+N₂ (1˜95%), H₂+He (1˜95%), etc., are repeated from one to about 10 times.

A this time, the force filling process may be performed by one of a single step of setting one of the pressure ranging from about 0.1 MPa to about 100 Mpa, a multi-step of multi-setting various pressure ranging from about 1 MPa to about 100 Mpa and a step of setting in a sine curve shape within the pressure ranging from about 0.1 MPa to about 100 Mpa.

Referring now to FIG. 1F, copper is deposited by electroless-plating method until the damascene pattern 4 is filled, thus forming a copper layer 6a.

Referring now to FIG. 1G, the copper layer 6a and the diffusion barrier layer 4 are polished by chemical mechanical polishing method until the surface of the interlayer insulating film 2 is exposed. Then, a post cleaning process is performed to form a copper line 6b within the damascene pattern 3.

As mentioned above, the disclosed methods can easily form a copper seed layer within a damascene pattern by simultaneously performing hydrogen reduction annealing process and force filling process while introducing spin-on process, and also easily form a selective copper line by depositing a copper layer using electroless-plating method.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed:

1. A method of manufacturing a metal line in a semiconductor device, comprising the steps of:
providing a substrate in which a damascene pattern is formed in an interlayer insulating film;
forming a diffusion barrier layer on the entire structure in which said damascene pattern is formed;
depositing a copper precursor on said diffusion barrier layer by means of a spin-on process;
changing said copper precursor into a porous copper layer by a baking process;
performing a hydrogen annealing process and a force filling process for said porous copper layer to form a copper seed layer at the bottom of said damascene pattern;
depositing copper by an electroless-plating method so that said damascene pattern can be sufficiently filled; and
forming a copper line by means of a chemical mechanical polishing method.

2. The method of manufacturing a metal line in a semiconductor device according to claim 1, wherein said interlayer insulating film comprises an insulating material having a low dielectric constant and said interlayer insulating film is formed by means of one of a spin-on process or a chemical vapor deposition method.

3. The method of manufacturing a metal line in a semiconductor device according to claim 1, wherein after said damascene pattern is formed, a cleaning process is performed, and wherein a RF plasma cleaning process is performed in the event that said damascene pattern exposes a base layer that comprises tungsten (Ti) or aluminum (Al), and a reactive cleaning process is performed in the event that said base layer is made of copper (Cu).

4. The method of manufacturing a metal line in a semiconductor device according to claim 1, wherein said diffusion barrier layer comprises a material selected from the group consisting of ionized PVD TiN, CVD TiN thin film, MOCVD TiN thin film, ionized PVD Ta, ionized PVD TaN, CVD Ta, CVD TaN, CVD WN, PVD TiAlN, PVD TiSiN, PVD TaSiN, CVD TiAlN, CVD TiSiN, and CVD TaSiN thin film.

5. The method of manufacturing a metal line in a semiconductor device according to claim 1, wherein said spin-on process spin-on deposits a copper precursor having a thickness of less than about 2000 Å at a temperature range from about 10° C. to about 100° C. at a rate ranging from about 100 rpm to about 8000 rpm.

6. The method of manufacturing a metal line in a semiconductor device according to claim 1, wherein said baking process is performed at a single temperature ranging from about 200° C. to about 500° C. for a time period ranging from about 1 second to about 10 minutes.

7. The method of manufacturing a metal line in a semiconductor device according to claim 1, wherein said baking process is performed at various temperatures ranging from about 200° C. to about 500° C. for a time period ranging from about 1 second to about 10 minutes.

8. The method of manufacturing a metal line in a semiconductor device according to claim 1, wherein said baking process is performed in the presence of an atmosphere selected from the group consisting of: hydrogen; hydrogen in combination with argon; and hydrogen in combination with nitrogen.

9. The method of manufacturing a metal line in a semiconductor device according to claim 1, wherein said hydrogen reduction annealing process and said force filling process are consecutively simultaneously performed after said baking process and are also performed at a temperature ranging from about 200° C. to about 500° C. for a time period ranging from about 1 second to about 10 minutes and the process is repeated from one to about 10 times.

10. The method of manufacturing a metal line in a semiconductor device according to claim 1, wherein said force filling process is performed at a pressure falling in a pressure range from about 0.1 MPa to about 100 Mpa.

11. The method of manufacturing a metal line in a semiconductor device according to claim 1, wherein said force filling process is performed under a plurality of pressures falling in the range of about 0.1 MPa to about 100 MPa.

12. The method of manufacturing a metal line in a semiconductor device according to claim 1, wherein said force filling process is performed under a varying pressure having a sine curve shape within a pressure range from about 0.1 MPa to about 100 Mpa.

13. The method of manufacturing a metal line in a semiconductor device according to claim 1, wherein said hydrogen reduction annealing process and said force filling process are performed under an atmosphere of a hydrogen gas or a mixture gas of hydrogen, argon, nitrogen and helium.

14. A semiconductor device comprising a method line and manufactured in accordance with the method of claim
